(19) United States
(12) Patent Application Publication
(10) Pub. No.: US 2009/0283814 A1
(43) Pub. Date: Nov. 19, 2009

(54) SINGLE-POLY NON-VOLATILE MEMORY CELL

(76) Inventors: Hsin-Ming Chen, Tainan Hsien (TW); Shao-Chang Huang, Hsinchu City (TW); Shih-Chen Wang, Taipei City (TW); Wen-Hao Ching, Hsinchu County (TW); Chrong-Jung Lin, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 12/122,739

(22) Filed: May 19, 2008

(51) Int. Cl. H01L 27/112

(52) U.S. Cl. 257/318; 257/E27.102

(57) ABSTRACT

A non-volatile memory cell includes an ion well of a semiconductor substrate; a first half-transistor having a firs select gate, a first diffusion region in the ion well, and a first gate dielectric layer between the first select gate and the ion well; a second half-transistor disposed adjacent to the first half-transistor, wherein the second half-transistor has a second select gate spaced apart from the first select gate, a second diffusion region in the ion well, and a second gate dielectric layer between the second select gate and the ion well. The first and second half-transistors are mirror-symmetrical to each other.

### BACKGROUND OF THE INVENTION

1. Field of the Invention

The present invention relates generally to the field of semiconductor non-volatile memory. In particular, the present invention relates to a single-poly, one-time programmable (OTP) memory cell.

2. Description of the Prior Art

Single-poly non-volatile memory is known in the art. Because of its high compatibility with existing CMOS logic processes, single-poly non-volatile memory has been widely applied in the field of embedded memory, embedded non-volatile memory in the mixed-mode circuits and micro-controllers among others.

U.S. Pat. No. 6,766,960 to Peng discloses a one and one-half transistor (1.5-T) semiconductor memory cell having a data storage element constructed around an ultra-thin dielectric. The semiconductor memory cell is used to store information by stressing the ultra-thin dielectric into breakdown (soft or hard breakdown) to set the on-state read current level of the memory cell.

FIG. 1 is a cross-sectional view of a 1.5-T semiconductor memory cell according to U.S. Pat. No. 6,766,960. As shown in FIG. 1, the 1.5-T semiconductor memory cell consists of a transistor 115 and half-transistor 111. To program the 1.5-T semiconductor memory cell, a positive voltage V_{R1}, for example, 2.5V, is applied to a row line R₁, a source voltage V_{S1}, for example, 0V, is applied to the source line and the source region 308, which is sufficient to turn on the transistor 115 and bring the drain 310 of the transistor 115 to 0V. A positive voltage V_{C1} such as 7V is applied to the gate 311 of the half-transistor 111. A gate oxide 312 in the half-transistor 111 is then broken down, which programs the memory cell.

The aforesaid 1.5-T semiconductor memory cell has several shortcomings. The thickness uniformity and quality of the gate oxide 312 located near an upper corner of the isolation trench 314 (as specifically indicated by circle 360) is poor, which results in poor programming uniformity. In addition, because of the lithographic constraints on the poly-poly spacing and the poly-active area (aka PO-OD) overlay along a channel length direction, each 1.5-T semiconductor memory cell occupies a relatively larger chip surface area, which hinders further miniaturization and cost reduction.

Canadian Patent No. 2520140 to Wlodek discloses an anti-fuse transistor that is employed in a non-volatile, one-time programmable (OTP) memory array application. FIG. 2 shows a cross-sectional view of an anti-fuse transistor 100 taken along the channel length direction of this device according to this patent. An anti-fuse transistor 100 includes a variable thickness gate oxide 102 formed on the substrate channel region 104, a polysilicon gate 106, sidewall spacers 108, first and second diffusion regions 110 and 112, and LDD regions 114. The variable thickness gate oxide 102 consists of a thick gate oxide and a thin gate oxide such that a portion of the channel length is covered by the thick gate oxide and the remaining portion of the channel length is covered by the thin gate oxide.

FIG. 3 is a cross-sectional view of another prior art OTP memory cell structure 101 that is similar to that disclosed in Canadian Patent No. 2520140. The difference between the OTP memory cell structure 101 and the anti-fuse transistor 100 of FIG. 2 is that the diffusion regions 112 and 114 of the anti-fuse transistor 100 are replaced with a shallow trench isolation (STI) structure 116. As shown in FIG. 3, a portion of the polysilicon gate 106 overlies the STI structure 116.

### SUMMARY OF THE INVENTION

It is one object of the present invention to provide an improved single-poly OTP memory cell, wherein a gate of the memory cell does not overlie an oxide trench or so-called shallow trench isolation along the channel length direction.

It is another object of the present invention to provide an improved single-poly OTP memory cell, which is fully compatible with existing or advanced CMOS logic processes such as 90 nm, 65 nm and 45 nm nodes, wherein no extra process layers are required.

According to the claimed invention, a single-poly non-volatile memory cell includes an ion well of first conductivity type of a semiconductor substrate; a first half-transistor comprising a first select gate, a first diffusion region of second conductivity type opposite to the first conductive type in the ion well, and a first gate dielectric layer between the first select gate and the ion well; and a second half-transistor disposed adjacent to the first half-transistor, the second half-transistor being mirror-identical to the first half-transistor and comprising a second select gate spaced apart and physically isolated from the first select gate, a second diffusion region of the second conductivity type in the ion well, and a second gate dielectric layer between the second select gate and the ion well.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 are cross-sectional views of prior art semiconductor memory cells.

FIG. 4 is a partial layout diagram of a portion of the memory array in accordance with one preferred embodiment of this invention.

FIG. 5 is a cross-sectional view taken along line I-I′ of FIG. 4 according to this invention.

FIG. 6 is a schematic circuit diagram demonstrating the program operation conditions for the memory cell corresponding to FIG. 4.

FIGS. 7 and 8 are schematic circuit diagrams demonstrating the read operation conditions for the memory cell according to this invention.

FIG. 9 is a top view showing the layout of a memory cell in accordance with another preferred embodiment of this invention.

FIG. 10 is a schematic, cross-sectional diagram taken along line III-III′ of FIG. 9.

FIG. 11 is a schematic circuit diagram demonstrating the program operation conditions for the memory cell corresponding to FIG. 10.

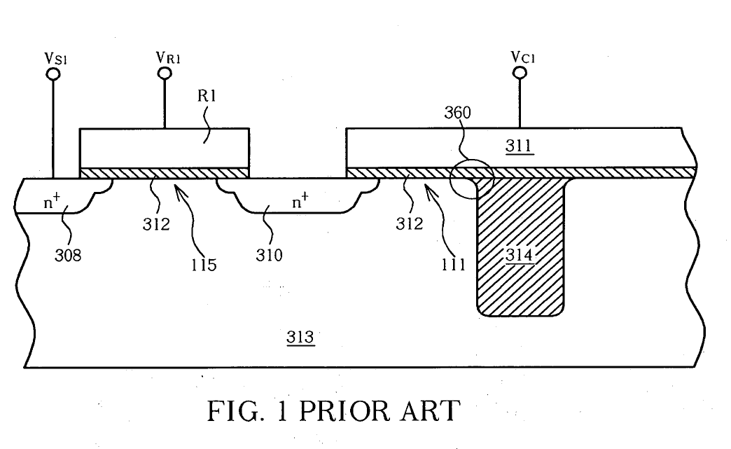

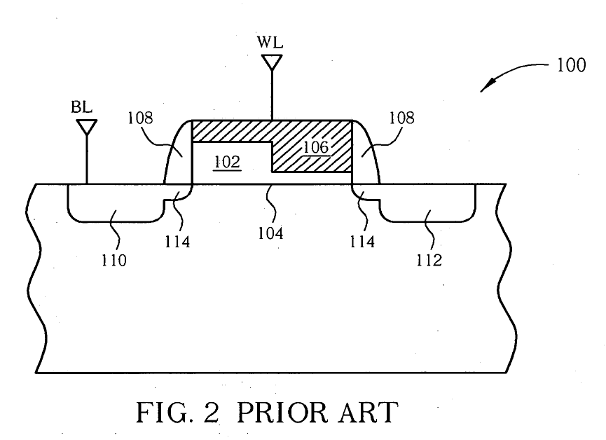

### DETAILED DESCRIPTION

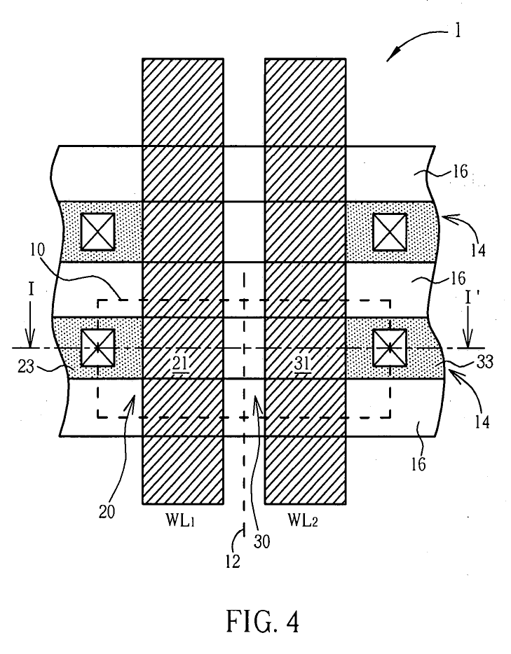

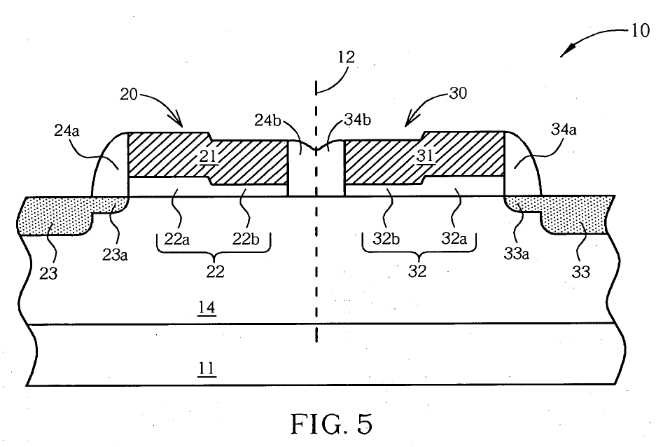

Please refer to FIG. 4 and FIG. 5. FIG. 4 is a partial layout diagram of a portion of the memory array 1 in accordance with one preferred embodiment of this invention. FIG. 5 is a cross-sectional view taken along line I-I′ of FIG. 4, which is the channel length direction of the non-volatile memory cell 10. The memory array 1 comprises columns of select gates or word lines, and rows of active areas.

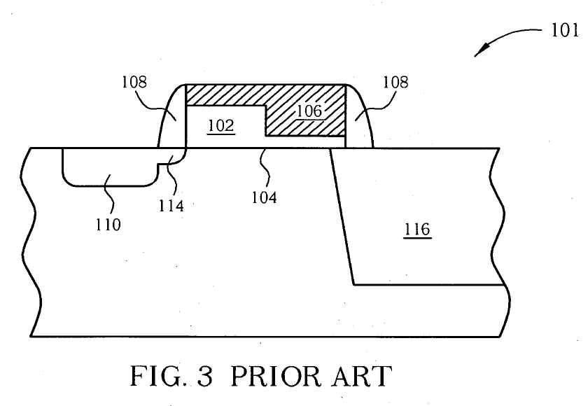

As shown in FIG. 4 and FIG. 5, the non-volatile memory cell 10 is fabricated on an ion well 14 such as a P well provided in a semiconductor substrate 11 such as a P-type silicon substrate. The ion well 14 is electrically isolated from adjacent ion wells by means of rows of distinguishing and physical STI structures and underlying anti-punch implantation 16. For the sake of simplicity, only two columns of select gates 21 and 31, ion well 14, and STI structures 16 are shown in FIG. 3.

According to the preferred embodiment of this invention, the non-volatile memory cell 10 includes two serially connected half-transistors 20 and 30. Structurally, the two half-transistors 20 and 30 are substantially mirror-symmetrical to each other with respect to the virtual mirror-symmetric line (or plane) 12. This virtual mirror-symmetric line 12 doesn't exist in this single poly memory cell physically, just for a very quick, easy and visualized way to explain the two half-transistors 20 and 30 are mirror-symmetrical to each other with respect to this virtual mirror-symmetric line 12.

The half-transistor 20 includes a select gate 21, a gate dielectric layer 22 between the select gate 21 and the ion well 14, sidewall spacers 24a and 24b, and diffusion regions 23 and 23a adjacent to the sidewall spacer 24a. The half-transistor 30 includes a select gate 31 spaced apart from the select gate 21, a gate dielectric layer 32 between the select gate 31 and the ion well 14, sidewall spacers 34a and 34b, and diffusion regions 33 and 33a disposed adjacent to the sidewall spacer 34a.

The diffusion regions 23a and 33a are also known as lightly doped drain (LDD) diffusion regions, also as a basic component for the MOSFET's source/drain area in advanced CMOS technology. The diffusion regions 23 and 33 are heavily doped diffusion regions. Optionally, a silicide layer may be added onto the select gates 21 and 31 or onto the surfaces of the diffusion regions 23 and 33 to reduce the sheet resistance on the gate and diffusion region.

According to the preferred embodiment of this invention, the select gates 21 and 31 are N⁺ doped polysilicon gates, and the diffusion regions 23, 23a, 33 and 33a are N type diffusion regions. It is understood that P type gates or diffusion regions can be implemented in other embodiments.

The gate dielectric layer 22 of the half-transistor 20 is divided into two portions: a thick gate dielectric portion 22a and a thin gate dielectric portion 22b. A portion of the channel length of the half-transistor 20 is covered by the thick gate dielectric portion 22a and the remaining portion of the channel length is covered by the thin gate dielectric portion 22b.

According to the preferred embodiment of this invention, the thick gate dielectric portion 22a has a thickness that is identical to that of an input/output transistor device in a peripheral circuit (often the thickest gate oxide region, not shown here), which typically ranges between 36 angstroms and 90 angstroms (for process technology nodes 0.35 um and below). The thin gate dielectric portion 22b has a thickness that is identical to that of a transistor device in a core circuit (often the thinnest gate oxide region, not shown here), which typically ranges between 10 angstroms and 36 angstroms.

Analogously, the gate dielectric layer 32 of the half-transistor 30 is divided into two portions: a thick gate dielectric portion 32a and a thin gate dielectric portion 32b. A portion of the channel length of the half-transistor 30 is covered by the thick gate dielectric portion 32a and the remaining portion of the channel length is covered by the thin gate dielectric portion 32b. The thick gate dielectric portion 32a has a thickness that ranges between 36 angstroms and 90 angstroms (for technology nodes 0.35 um and below). The thin gate dielectric portion 32b has a thickness that ranges between 10 angstroms and 36 angstroms.

According to this invention, the thickness of the thick gate dielectric portion 22a and the thickness of the thick gate dielectric portion 32a are substantially the same. The thickness of the thin gate dielectric portion 22b and the thickness of the thin gate dielectric portion 32b are substantially the same.

According to this invention, to meet symmetric purpose of these two half transistors, the channel length with thick gate dielectric portion 22a of half transistor 20 are designed to be the same with that of thick gate dielectric portion 32a of half transistor 30 in terms of layout perspective. But in real case, due to the silicon wafer's manufacturing process issue, especially photo lithography misalignment, etching rate, etc., these two channel lengths may not be real identical.

Since the spaced apart select gate 21 and select gate 31 are in close proximity to each other, the sidewall spacer 24b and the sidewall spacer 34b approximately fill the spacing therebetween. The sidewall spacer 24b merges with the sidewall spacer 34b between the select gate 21 and select gate 31 and produces a recessed surface profile.

According to this invention, the memory cell is designed with no mentioned lightly doped drain (LDD) diffusion regions (such as region 23a or 33a) underneath the sidewall spacer areas (24b and 34b). Also, the memory cell is designed with no mentioned heavily doped diffusion regions (such as region 23 or 33) underneath the sidewall spacer areas (24b and 34b). Without the formation of source/drain diffusion region, the channel stop between half transistor 20 and half transistor 30 is naturally established underneath the sidewall spacer areas (24b and 34b).

It is noteworthy that no junctions are formed directly under the sidewall spacer 24b and the sidewall spacer 34b within the ion well 14. The substrate surface between the select gates 21 and 31 is masked when implementing ion implantation process for implanting dopants species into the ion well 14 to form diffusion regions 23a and 33a.

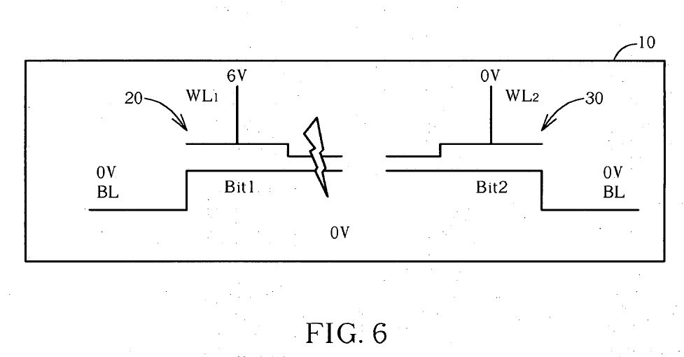

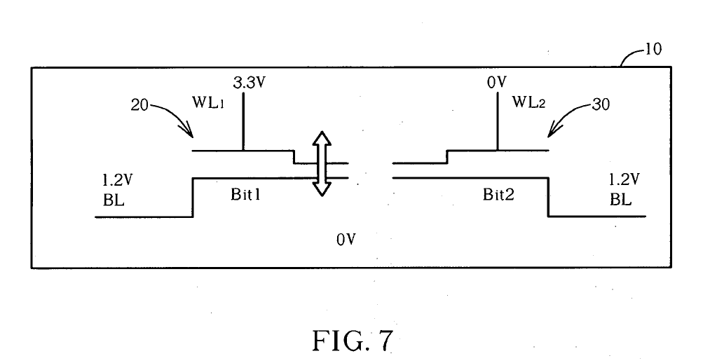

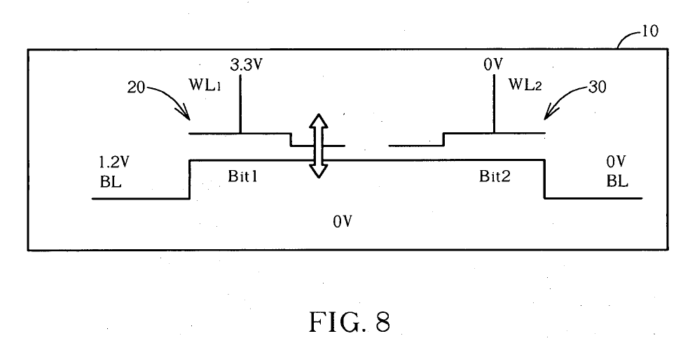

The non-volatile memory cell 10 as set forth in FIG. 4 is a two-bit-per-cell memory device that utilizes a breakdown phenomenon in the thin gate dielectric layer 22b or 32b to store digital information. FIG. 6 is a schematic memory cell diagram demonstrating exemplary program operation conditions for the memory cell corresponding to FIG. 4. FIGS. 7 and 8 are schematic circuit diagrams demonstrating exemplary read operation conditions for the memory cell according to this invention. It is noted that although the two half-transistors 20 and 30 are formed in the same active area, there is no junction formed therebetween. The well concentration directly underneath the spacers 24b and 34b may be increased such that although the cell seems like a split gate structure in a schematic plot, in fact, they are two electrically independent cells.

Referring to FIG. 6 and briefly back to FIG. 5, to write a left-bit (denoted as “Bit 1” in FIG. 6) into the half-transistor 20 of the non-volatile memory cell 10, a relatively high voltage such as 6V is applied to the select gate 21 or WL1, the diffusion region 23 is connected to a relatively lower bit line (BL) voltage such as ground voltage or 0V, and the ion well 14 is also grounded. Under the aforesaid program conditions, two results may occur depending on the scale of damage imposed on the gate oxide: (1) in a soft breakdown case, a leakage path toward the well is formed in the gate oxide, (2) in a hard breakdown case, the thin gate dielectric layer 22b is broken down to form an tiny N⁺-P diode on surface channel region 22b and to separate from the select gate 21 to the ion well 14, avoiding further leakage current flow.

During programming, with the assistance of natural channel stop formation underneath the sidewall spacer areas (24b and 34b), the half-transistor 30 is electrically isolated from the half-transistor 20 by applying a relatively lower voltage such as ground voltage or 0V to the select gate 31 (WL2) and a relatively lower voltage such as ground voltage or 0V to the diffusion region 33.

The right-bit (denoted as “Bit 2”) can be written into the half-transistor 30 in the same manner, for example, by coupling the select gate 31 to a relatively high voltage such as 6V and grounding the select gate 21, the diffusion regions 23 and 33, and grounding the ion well 14.

Referring now to FIG. 7 and briefly to FIG. 5, to read the left-bit written into the half-transistor 20 of the non-volatile memory cell 10, a voltage such as 3.3V is applied to the select gate 21 or WL1, the diffusion regions 23 and 33 are connected to a bit line voltage such as 1.2V, and the ion well 14 and the select gate 31 are grounded. The right-bit can be read in the same manner.

FIG. 8 is another example to read the left-bit stored in the half-transistor 20 of the non-volatile memory cell 10. The voltage conditions are pretty much the same as those shown in FIG. 7 except that the diffusion region 33 of the half-transistor 30 is grounded.

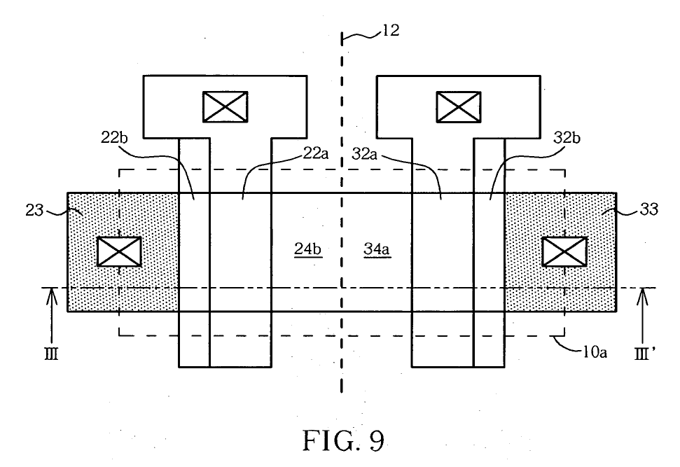

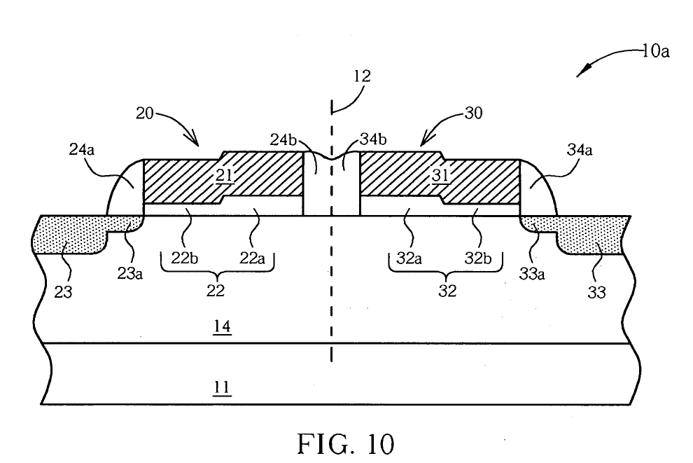

Please refer to FIG. 9 and FIG. 10. FIG. 9 is a top view showing the layout of a memory cell 10a in accordance with another preferred embodiment of this invention. FIG. 10 is a schematic, cross-sectional diagram taken along line III-III′ of FIG. 9. As shown in FIG. 9 and FIG. 10, the difference between the memory cell 10 as set forth in FIG. 5 and the memory cell 10a as set forth in FIG. 10 is that the thin gate dielectric layer 22b of the half-transistor 20a of the memory cell 10a is close to the LDD region 23a and is between the thick gate dielectric layer 22a and the LDD region 23a. The thin gate dielectric layer 32b of the half-transistor 30a of the memory cell 10a is close to the LDD region 33a and is between the thick gate dielectric layer 32a and the LDD region 33a. The memory cell 10a is still a symmetric cell structure and mirror identically to the virtual symmetric line 12.

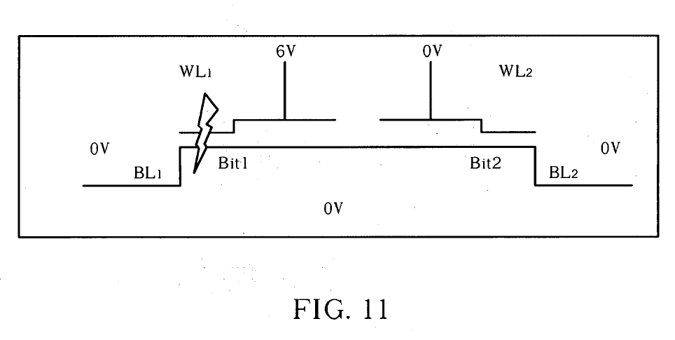

Referring to FIG. 11 and briefly back to FIG. 10, to write a left-bit (denoted as “Bit 1” in FIG. 11 ) into the half-transistor 20a of the non-volatile memory cell 10a, a relatively high voltage such as 6V is applied to the select gate 21 or WL1, the diffusion region 23 is connected to a relatively lower bit line (BL) voltage such as ground voltage or 0V, and the ion well 14 is also grounded. Under the aforesaid program conditions, the thin gate dielectric layer 22b is broken down to form an tiny N⁺-P diode on surface channel region 22b and to separate from the select gate 21 to the ion well 14, avoiding further leakage current flow.

During programming, with the assistance of natural channel stop formation underneath the sidewall spacer areas (24b and 34b), the half-transistor 30a is electrically isolated from the half-transistor 20a by applying a relatively lower voltage such as ground voltage or 0V to the select gate 31 (WL2) and a relatively lower voltage such as ground voltage or 0V to the diffusion region 33.

The right-bit (denoted as “Bit 2”) can be written into the half-transistor 30a in the same manner, for example, by coupling the select gate 31 to a relatively high voltage such as 6V and grounding the select gate 21, the diffusion regions 23 and 33, and grounding the ion well 14.

Those skilled in the art will readily observe that numerous modifications and alterations of the device and method may be made while retaining the teachings of the invention.

What is claimed is:

1. A non-volatile memory cell, comprising:
an ion well of first conductivity type of a semiconductor substrate;
a first half-transistor comprising a first select gate, a first diffusion region of second conductivity type opposite to said first conductive type in said ion well, and a first gate dielectric layer between said first select gate and said ion well; and
a second half-transistor disposed adjacent to said first half-transistor, said second half-transistor being mirror-identical to said first half-transistor and comprising a second select gate spaced apart and physically isolated from said first select gate, a second diffusion region of said second conductivity type in said ion well, and a second gate dielectric layer between said second select gate and said ion well.

2. The non-volatile memory cell according to claim 1 wherein no junction is formed in said ion well between said first and second select gates.

3. The non-volatile memory cell according to claim 1 wherein said first gate dielectric layer has a first thick portion and a first thin portion.

4. The non-volatile memory cell according to claim 3 wherein said first thick portion has a thickness ranging between 5 angstroms and 90 angstroms.

5. The non-volatile memory cell according to claim 3 wherein said first thin portion has a thickness less 35 angstroms.

6. The non-volatile memory cell according to claim 1 wherein said second gate dielectric layer has a second thick portion and a second thin portion.

7. The non-volatile memory cell according to claim 6 wherein said second thick portion has a thickness ranging between 5 angstroms and 90 angstroms.

8. The single-poly non-volatile memory cell according to claim 6 wherein said second thin portion has a thickness less than 35 angstroms.

9. The non-volatile memory cell according to claim 1 wherein said first half-transistor comprises a first sidewall spacer and said second half-transistor comprises a second sidewall spacer, and wherein said first sidewall spacer and said second sidewall spacer fill the space between said spaced apart first select gate and second select gate.

10. The non-volatile memory cell according to claim 9 wherein said first sidewall spacer merges with said second sidewall spacer between said first select gate and said second select gate and produces a recessed surface profile thereto.

11. The non-volatile memory cell according to claim 9 wherein no source/drain region is formed under said first and second sidewall spacers.

12. The non-volatile memory cell according to claim 1 wherein said first conductivity type is P type and said second conductivity type is N type.

13. The non-volatile memory cell according to claim 1 wherein said single-poly non-volatile memory cell is a two-bit-per-cell memory device.
